(19) United States
(12) Patent Application Publication
(10) Pub. No.: US 2026/0082538 A1
(43) Pub. Date: Mar. 19, 2026

(54) POLYSILICON MEMORY STRUCTURE AND MANUFACTURING METHOD THEREOF

(71) Applicant: NATIONAL CHIN-YI UNIVERSITY OF TECHNOLOGY, TAICHUNG CITY (TW)

(72) Inventor: PO-YI KUO, TAICHUNG CITY (TW)

(73) Assignee: NATIONAL CHIN-YI UNIVERSITY OF TECHNOLOGY, TAICHUNG CITY (TW)

(21) Appl. No.: 18/886,281

(22) Filed: Sep. 16, 2024

(51) Int. Cl. H10B 12/00

(52) U.S. Cl. CPC H10B 12/20; H10B 12/01

(57) ABSTRACT

A polysilicon memory structure includes a silicon base material layer, a silicon dioxide layer, a polysilicon memory channel, a dielectric layer, and a conductive layer. The silicon dioxide layer is stacked on the silicon base material layer, with a channel setting region disposed on a portion of a surface of the silicon dioxide layer away from the silicon base material layer. The polysilicon memory channel is disposed in the channel setting region and has a partially depleted floating body storage region therein. The dielectric layer is stacked on the silicon dioxide layer and the polysilicon memory channel, and covers a periphery of the polysilicon memory channel. The conductive layer is stacked on the dielectric layer.

### BACKGROUND OF THE INVENTION

### 1. Field of the Invention:

The present invention relates to structures and manufacturing methods thereof, and more particularly, to a polysilicon memory structure and manufacturing method thereof.

### 2. Description of the Related Art:

A conventional dynamic random access memory (DRAM) requires a low-leakage single-crystal silicon transistor and a capacitor to form a one-transistor-one-capacitor (1T1C) structure. Therefore, DRAM components are typically not included in the back-end processes of monolithic 3D ICs. A conventional DRAM requires a 1T1C structure. However, due to the capacity limitation of a capacitor, the scaling down process thereof is impeded. To improve such issues, many references have proposed that a capacitor-less single-transistor dynamic random access memory (1T-DRAM) with a floating body (FB) structure could replace the conventional 1T1C-DRAM.

The basic structure of a 1T-DRAM is similar to that of a conventional single-crystal silicon structure on an insulating layer, but with a floating body. Essentially, it has a parasitic bipolar junction transistor (BJT). The memory function is achieved by sensing the difference of the drain current (ID) between state 0 and state 1. The difference is caused by the change in the potential of the floating body (FB) under appropriate bias conditions. The potential of the floating body is allowed to be altered by generating electron-hole pairs through impact ionization which leads to hole accumulation. Under appropriate bias conditions, a memory window is created by turning the parasitic BJT on or off, so as to allow the reading of the difference in the drain current (ID) between state 0 and state 1. However, the memory retention time thereof typically ranges from 1 to 10 seconds, which is only slightly longer than that of the traditional DRAM, resulting in a less optimal utility.

### SUMMARY OF THE INVENTION

The present invention aims at improving the issues of the relatively limited memory window and retention time of the capacitor-less single-transistor dynamic random access memory (1T-DRAM).

To achieve the objective above, an embodiment of the present invention provides a polysilicon memory structure, comprising:
a silicon base material layer;
a silicon dioxide layer stacked on the silicon base material layer, with a channel setting region disposed on a portion of a surface of the silicon dioxide layer away from the silicon base material layer;
a polysilicon memory channel disposed in the channel setting region and having a partially depleted floating body storage region therein;
a dielectric layer stacked on the silicon dioxide layer and the polysilicon memory channel, and covering a periphery of the polysilicon memory channel; and
a conductive layer stacked on the dielectric layer.

Also, the present invention provides a manufacturing method of a polysilicon memory structure, comprising following steps:
a substrate setting step, providing a substrate having a silicon base material layer and a silicon dioxide layer sequentially stacked from bottom to top;
a channel formation step, depositing an undoped polysilicon layer on the silicon dioxide layer through a chemical vapor deposition method, and performing a partial etching on the undoped polysilicon layer to form a polysilicon memory channel having a partially depleted floating body storage region therein;
a dielectric layer setting step, depositing a dielectric layer on the silicon dioxide layer and the polysilicon memory channel through a chemical vapor deposition method, so that the dielectric layer covers a periphery of the polysilicon memory channel; and
a conductive layer setting step, depositing a conductive layer on the dielectric layer through a chemical vapor deposition method.

Accordingly, by utilizing the partially depleted floating body storage region within the polysilicon memory channel, the present invention is able to store a large number of holes, thereby enhancing the overall performance of the memory, such as achieving a larger memory window (greater than 4V), a longer memory retention time (over 1000 seconds), and a smaller subthreshold swing in the on-state and off-state (less than 60 mV/dec.).

### BRIEF DESCRIPTION OF THE DRAWINGS

FIG. 1 is a flow chart of the manufacturing method of polysilicon memory structure in accordance with an embodiment of the present invention.

FIG. 2 is a schematic view illustrating the position of the polysilicon memory structure in accordance with an embodiment of the present invention located on the transistor.

FIG. 3 is a cross-sectional view taken along line A-A in FIG. 2, illustrating the substrate structure in the substrate setting step in FIG. 1.

FIG. 4 is another cross-sectional view taken along line A-A in FIG. 2, illustrating the structure formed corresponding to the channel formation step in FIG. 1.

FIG. 5 is another cross-sectional view taken along line A-A in FIG. 2, illustrating the structure formed corresponding to the channel formation step in FIG. 1.

FIG. 6 is another cross-sectional view taken along line A-A in FIG. 2, illustrating the polysilicon memory structure formed corresponding to the dielectric layer setting step and the conductive layer setting step in FIG. 1.

FIG. 7 is another flow chart of the manufacturing method of polysilicon memory structure in accordance with another embodiment of the present invention.

FIG. 8 is another cross-sectional view taken along line A-A in FIG. 2, illustrating the structure formed corresponding to the channel formation step in FIG. 7.

FIG. 9 is another cross-sectional view taken along line A-A in FIG. 2, illustrating the structure formed corresponding to the spacer layer setting step in FIG. 7.

FIG. 10 is another cross-sectional view taken along line A-A in FIG. 2, illustrating the polysilicon memory structure formed corresponding to the dielectric layer setting step and the conductive layer setting step in FIG. 7.

FIG. 11 is another flow chart of the manufacturing method of polysilicon memory structure in accordance with another embodiment of the present invention.

FIG. 12 is a schematic view illustrating the position of the polysilicon memory structure in accordance with another embodiment of the present invention located on the transistor.

FIG. 13 is a cross-sectional view taken along line B-B in FIG. 12, illustrating the structure formed from the substrate setting step to the second oxide layer formation step in FIG. 11.

FIG. 14 is another cross-sectional view taken along line B-B in FIG. 12, illustrating the structure formed corresponding to the raised source/drain formation step in FIG. 11.

FIG. 15 is another cross-sectional view taken along line B-B in FIG. 12, illustrating the structure formed corresponding to the raised source/drain formation step in FIG. 11.

FIG. 16 is another cross-sectional view taken along line B-B in FIG. 12, illustrating the structure formed corresponding to the raised source/drain formation step in FIG. 11.

FIG. 17 is another cross-sectional view taken along line B-B in FIG. 12, illustrating the polysilicon memory structure formed corresponding to the oxide layer etching step in FIG. 11.

FIG. 18 is another cross-sectional view taken along line B-B in FIG. 12, illustrating the polysilicon memory structure formed corresponding to the dielectric layer setting step and the conductive layer setting step in FIG. 11.

FIG. 19 is a structural schematic view of the polysilicon memory structure in accordance with another embodiment of the present invention, illustrating it having a plurality of polysilicon memory channels.

FIG. 20 is a schematic view illustrating the curve relationship between the gate voltage and the drain current in accordance with the present invention.

### DETAILED DESCRIPTION OF THE INVENTION

The aforementioned and further advantages and features of the present invention will be understood by reference to the description of the preferred embodiment in conjunction with the accompanying drawings where the components are illustrated based on a proportion for explanation but not subject to the actual component proportion.

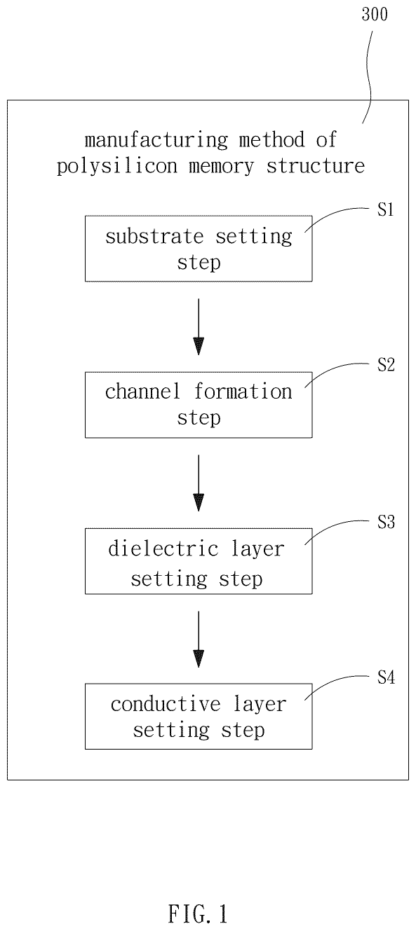

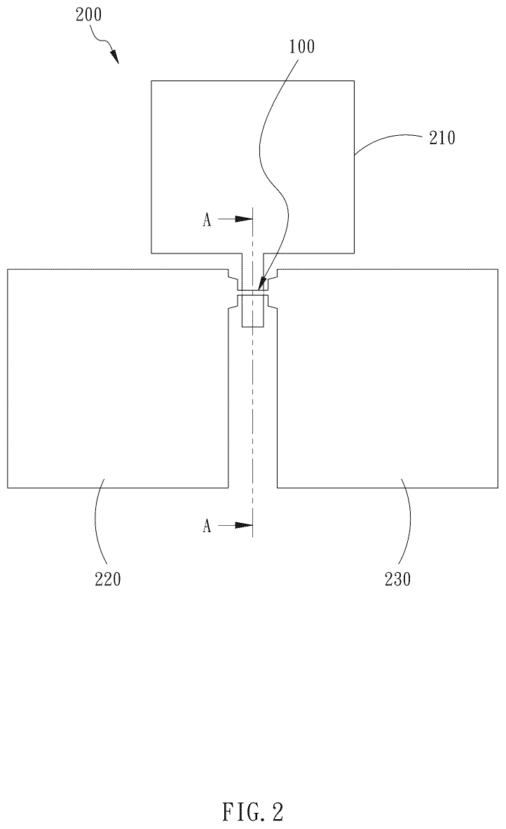

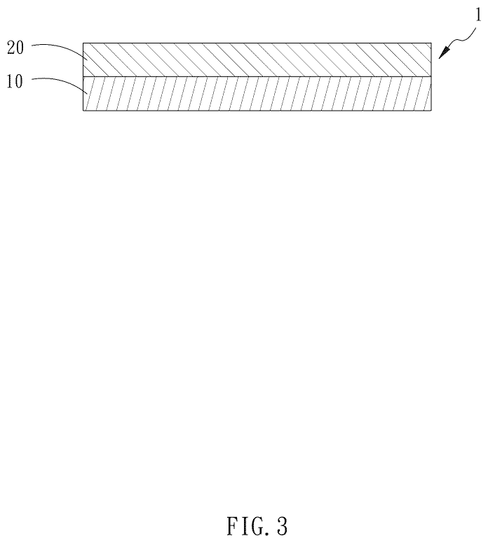

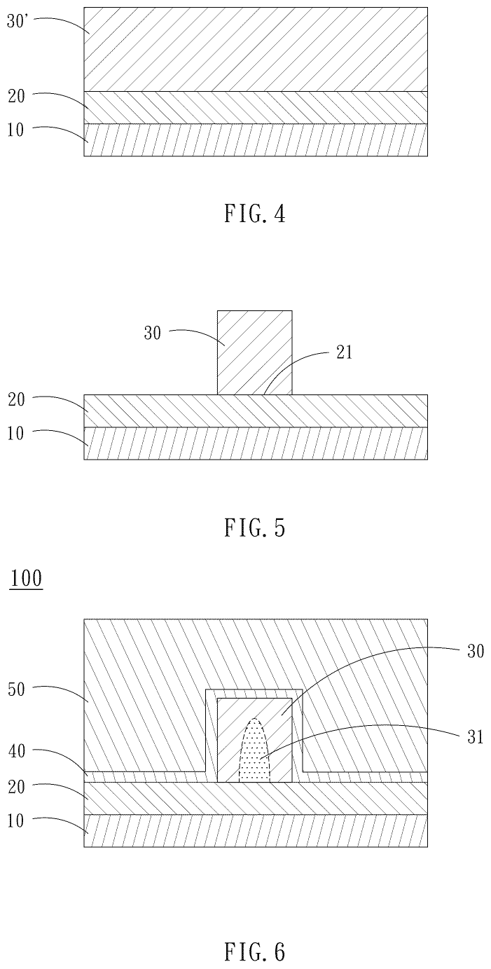

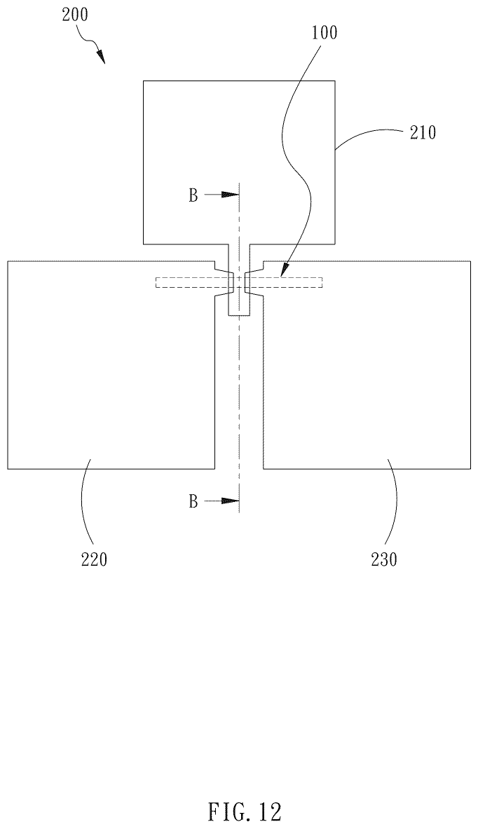

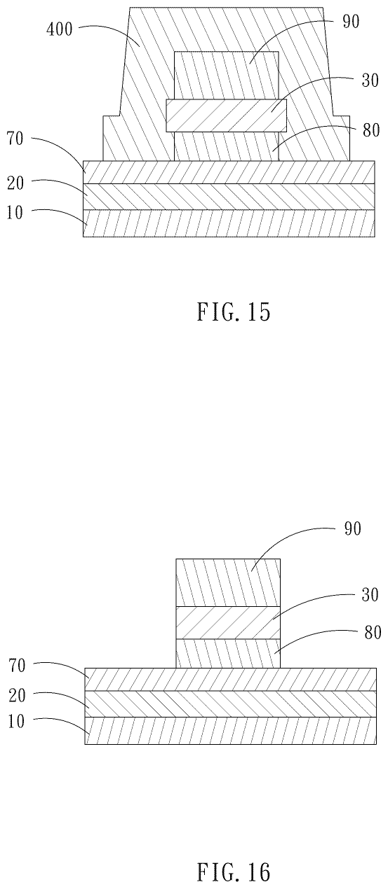

Referring to FIG. 1 to FIG. 20, a polysilicon memory structure 100, comprising a silicon base material layer 10, a silicon dioxide layer 20, a polysilicon memory channel 30, a dielectric layer 40, and a conductive layer 50. Therein, the present invention is disposed on a transistor 200 having a gate region 210, a source region 220, and a drain region 230. The present invention is located in the gate region 210 and in communication with the source region 220 and the drain region 230.

The silicon dioxide layer 20 is stacked on the silicon base material layer 10, with a channel setting region 21 disposed on a portion of a surface of the silicon dioxide layer 20 away from the silicon base material layer 10.

The polysilicon memory channel 30 is disposed in the channel setting region 21. The polysilicon memory channel 30 comprises a partially depleted floating body storage region 31 therein. The polysilicon memory channel 30 is formed of small-grain polysilicon. In the embodiment, an amorphous silicon is first deposited on the silicon dioxide layer 20 through the low-pressure chemical vapor deposition (LPCVD) or plasma-enhanced chemical vapor deposition (PECVD) method, and the amorphous silicon is then crystallized into small-grain polysilicon through the solid phase crystallization (SPC) or rapid thermal annealing (RTA) method. In another embodiment of the present invention, the small-grain polysilicon is also allowed to be directly deposited through the LPCVD or PECVD method.

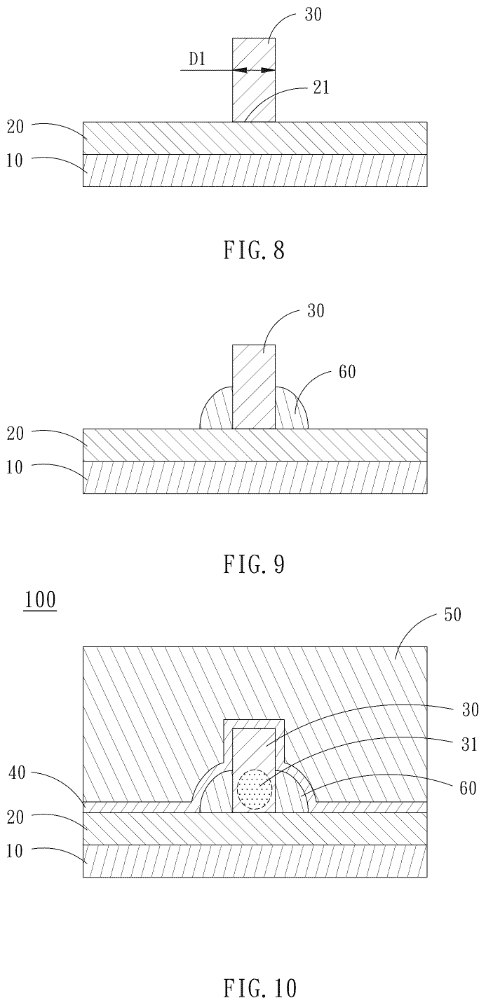

Referring to FIG. 8 to FIG. 10, in the embodiment, the polysilicon memory channel 30 has a channel width D1. When the channel width D1 is smaller than a width threshold value (50 nanometers in the embodiment), the polysilicon memory structure 100 further comprises a spacer layer 60, which is disposed on two sides of the polysilicon memory channel 30 and arranged at the junction between the polysilicon memory channel 30 and the silicon dioxide layer 20. Therein, the spacer layer 60 is allowed to be deposited through the low-pressure chemical vapor deposition (LPCVD) method and formed of tetraethoxysilane (TEOS). Therefore, when the channel width D1 of the polysilicon memory channel 30 is smaller than the specified width threshold value, a fully depleted (FD) floating body (FB) is formed under the influence of the dielectric layer 40. Thus, by incorporating the spacer layer 60, the polysilicon memory channel 30 is located closer to the bottom of the silicon dioxide layer 20, so as to form the partially depleted floating body storage region 31, which is applied to effectively store a large number of holes, thereby enhancing the overall memory performance of the present invention (such as achieving a larger memory window, longer memory retention time, etc.).

The dielectric layer 40 is stacked on the silicon dioxide layer 20 and the polysilicon memory channel 30, and covers the periphery of the polysilicon memory channel 30. Therein, the material of the dielectric layer 40 is allowed to be tetraethoxysilane or a dielectric material having a high dielectric constant. The dielectric layer 40 is applied as a gate dielectric layer.

The conductive layer 50 is stacked on the dielectric layer 40. Therein, the material of the conductive layer 50 is allowed to be metal or n⁺ doped polysilicon. The conductive layer 50 is applied as a gate conductive layer.

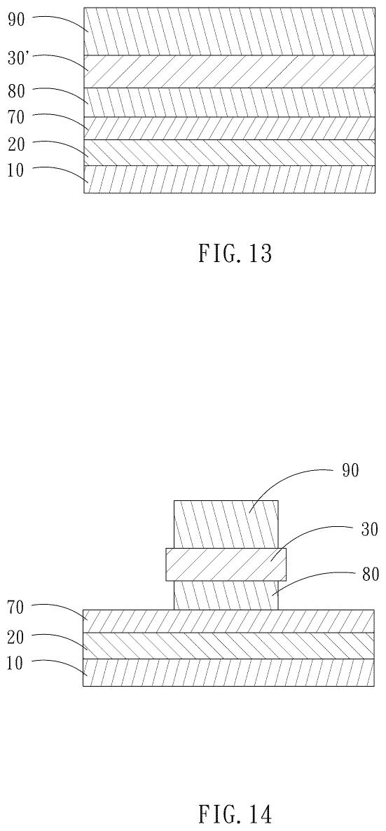

Referring to FIG. 13 to FIG. 19, in another embodiment, the polysilicon memory structure 100 also comprises a silicon nitride layer 70, a first tetraethoxysilane layer 80, and a second tetraethoxysilane layer 90. The silicon nitride layer 70 is stacked on one side of the silicon dioxide layer 20 away from the silicon base material layer 10. The silicon nitride layer 70 is used to prevent the oxide under the source region 220 or the drain region 230 from being hollowed during the subsequent channel suspending process, thereby preventing the formation of parasitic gates and reducing leakage paths. The first tetraethoxysilane layer 80 is disposed between the silicon nitride layer 70 and the polysilicon memory channel 30, and the second tetraethoxysilane layer 90 is disposed on the polysilicon memory channel 30. Therein, the first tetraethoxysilane layer 80 and the second tetraethoxysilane layer 90 are allowed to be deposited through the low-pressure chemical vapor deposition (LPCVD) method.

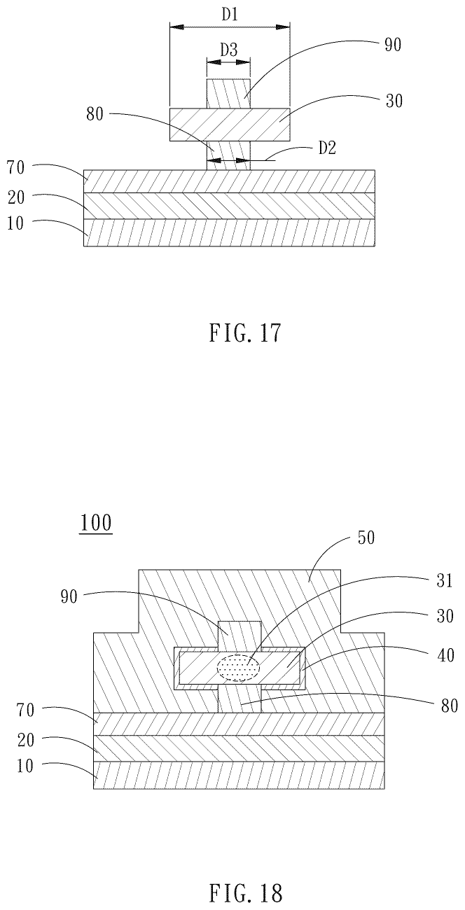

Referring to FIG. 17 and FIG. 18, in another embodiment, the first tetraethoxysilane layer 80 has a first width D2, and the second tetraethoxysilane layer 90 has a second width D3, wherein the first width D2 is smaller than the channel width D1, and the second width D3 is smaller than the channel width D1. Therefore, the two sides of the polysilicon memory channel 30 protrude out of the first tetraethoxysilane layer 80 and the second tetraethoxysilane layer 90. Because the polysilicon memory channel 30 undergoes different degrees of gate control between its left/right side and its center, the central portion of the polysilicon memory channel 30 will be the most partially depleted portion of the floating body (FB) region. Therefore, in the embodiment, the partially depleted floating body storage region 31 is located in the central region of the polysilicon memory channel 30. Also, the partially depleted floating body storage region 31 effectively stores a large number of holes, so as to enhance the overall memory performance of the present invention (such as achieving a larger memory window, longer memory retention time, etc.).

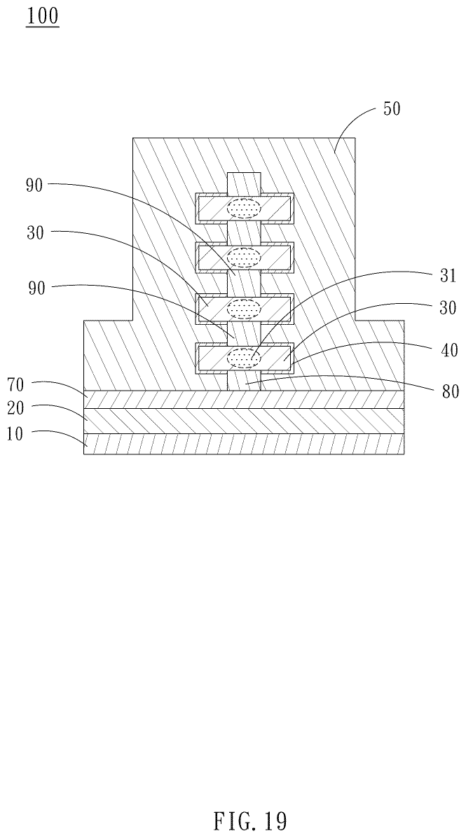

Referring to FIG. 19, in another embodiment, a plurality of polysilicon memory channels 30 is included, and a plurality of second tetraethoxysilane layers 90 is included, wherein the polysilicon memory channels 30 and the second tetraethoxysilane layers 90 are disposed in an interleaved arrangement. With such configuration, the plurality of polysilicon memory channels 30 have multiple partially depleted floating body storage regions 31, so that the storage of a larger number of holes is achieved, thereby further enhancing the overall memory performance of the present application (such as achieving a larger memory window, longer memory retention time, etc.).

Referring to FIG. 1, in the embodiment, a manufacturing method 300 of polysilicon memory structure is provided, comprising a substrate setting step S1, a channel formation step S2, a dielectric layer setting step S3, and a conductive layer setting step S4.

In the substrate setting step S1, a substrate 1 is provided. The substrate 1 comprises a silicon base material layer 10 and a silicon dioxide layer 20 sequentially stacked from bottom to top thereof. Therein, a channel setting region 21 is disposed on a portion of a surface of the silicon dioxide layer 20 away from the silicon base material layer 10.

In the channel formation step S2, an undoped polysilicon layer 30′ is deposited on the silicon dioxide layer 20 through a chemical vapor deposition method, and the undoped polysilicon layer 30′ undergoes a partial etching process to form a polysilicon memory channel 30, wherein the polysilicon memory channel 30 comprises a partially depleted floating body storage region 31 therein. In the embodiment, during the partial etching process, the undoped polysilicon layer 30′ deposited outside the channel setting region 21 is removed, so that the undoped polysilicon layer 30′ located in the channel setting region 21 becomes the polysilicon memory channel 30. The undoped polysilicon layer 30′ is deposited on the silicon dioxide layer 20 through the low-pressure chemical vapor deposition (LPCVD) or plasma-enhanced chemical vapor deposition (PECVD) method.

In the dielectric layer setting step S3, a dielectric layer 40 is deposited on the silicon dioxide layer 20 and the polysilicon memory channel 30 through a chemical vapor deposition method, so that the dielectric layer 40 covers a periphery of the polysilicon memory channel 30. Therein, the material of the dielectric layer 40 is allowed to be tetraethoxysilane or a dielectric material having a high dielectric constant. The dielectric layer 40 is applied as a gate dielectric layer. The dielectric layer 40 is deposited through the low-pressure chemical vapor deposition (LPCVD) or plasma-enhanced chemical vapor deposition (PECVD) method.

In the conductive layer setting step S4, a conductive layer 50 is deposited on the dielectric layer 40 through a chemical vapor deposition method. Therein, the material of the conductive layer 50 is allowed to be metal or n⁺ doped polysilicon. The conductive layer 50 is applied as a gate conductive layer. The conductive layer 50 is deposited through the low-pressure chemical vapor deposition (LPCVD) or plasma-enhanced chemical vapor deposition (PECVD) method.

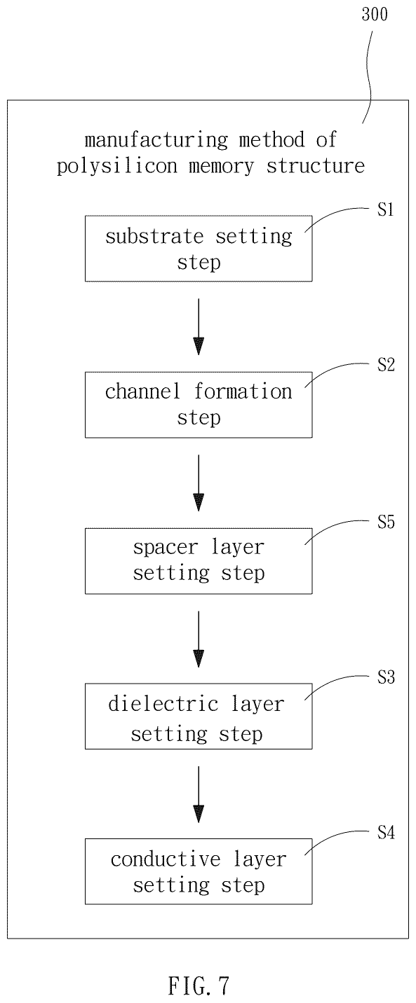

Referring to FIG. 7, in another embodiment, before the dielectric layer setting step S3, a spacer layer setting step S5 is included. If the channel width D1 of the polysilicon memory channel 30 is smaller than the width threshold value, a spacer layer 60 is deposited on two sides of the polysilicon memory channel 30 through the chemical vapor deposition method. Therein, the spacer layer 60 is disposed at the junction between the polysilicon memory channel 30 and the silicon dioxide layer 20. Therefore, when the channel width D1 of the polysilicon memory channel 30 is smaller than the specified width threshold value, a fully depleted (FD) floating body (FB) is formed under the influence of the dielectric layer 40. Thus, by incorporating the spacer layer 60, the polysilicon memory channel 30 is located closer to the bottom of the silicon dioxide layer 20, so as to form the partially depleted floating body storage region 31, which is applied to effectively store a large number of holes, thereby enhancing the overall memory performance of the present invention (such as achieving a larger memory window, longer memory retention time, etc.).

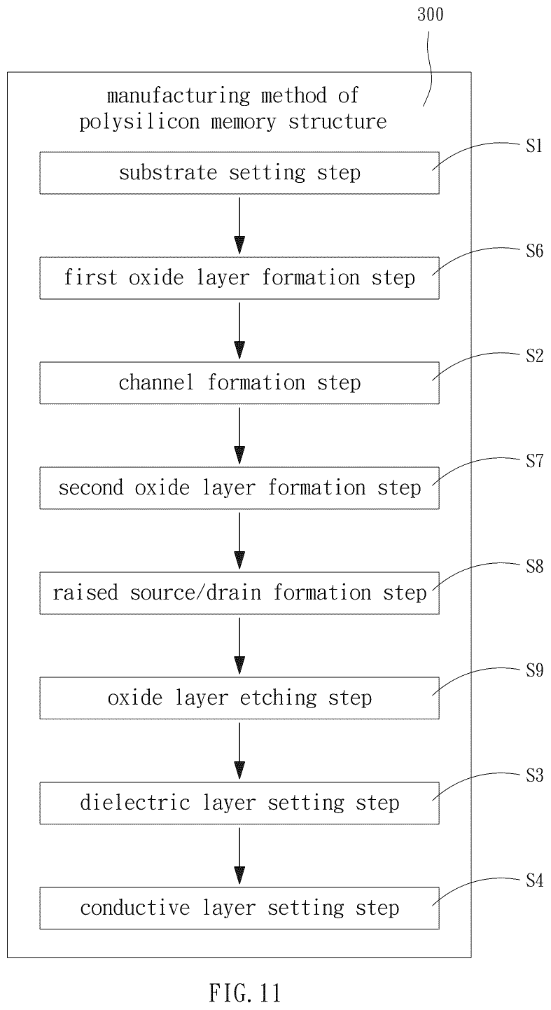

Referring to FIG. 11 to FIG. 13, in another embodiment, during the substrate setting step S1, the substrate 1 further comprises a silicon nitride layer 70, which is stacked on one side of the silicon dioxide layer 20 away from the silicon base material layer 10. The silicon nitride layer 70 is used to prevent the oxide under the source region 220 or the drain region 230 from being hollowed during the subsequent channel suspending process, thereby preventing the formation of parasitic gates and reducing leakage paths.

Referring to FIG. 11 to FIG. 13, in another embodiment, before the channel formation step S2, a first oxide layer formation step S6 is included, wherein a first tetraethoxysilane layer 80 is formed between the silicon nitride layer 70 and the polysilicon memory channel 30 through a chemical vapor deposition method. After the channel formation step S2, a second oxide layer formation step S7 is included, wherein a second tetraethoxysilane layer 90 is formed on the polysilicon memory channel 30 through a chemical vapor deposition method.

Referring to FIG. 11 to FIG. 16, in another embodiment, after the second oxide layer formation step S7, a raised source/drain formation step S8 is included, wherein a doped polysilicon layer 400 is deposited on the silicon nitride layer 70, and the doped polysilicon layer 400 covers the first tetraethoxysilane layer 80, the polysilicon memory channel 30, and the second tetraethoxysilane layer 90; also, the doped polysilicon layer 400 undergoes a selective etching process to form a raised source in the source region 220 (not shown) and a raised drain in the drain region 230 (not shown). Therein, the doped polysilicon layer 400 is formed of n⁺ doped polysilicon. The raised source/drain significantly lowers the parasitic series source/drain resistance (parasitic series R_{S/D}), so as to enhance the conductive nature of the components. Further, the raised source and raise drain are deposited on the silicon nitride layer 70, preventing the underlying silicon dioxide layer 20 from being hollowed out to form holes, thereby preventing the subsequent formation of parasitic gates and reducing leakage paths.

Furthermore, during the raised source/drain formation step S8, the first tetraethoxysilane layer 80 and the second tetraethoxysilane layer 90 first undergo a partial etching process, so as to increase the contact area between the polysilicon memory channel 30 and the doped polysilicon layer 400, and facilitate the subsequent formation of the raised source and raised drain.

Referring to FIG. 11 to FIG. 17, in another embodiment, after the raised source/drain formation step S8, an oxide layer etching step S9 is included, wherein the first tetraethoxysilane layer 80 and the second tetraethoxysilane layer 90 are partially etched, such that the polysilicon memory channel 30 protrudes from the first tetraethoxysilane layer 80 and the second tetraethoxysilane layer 90. The first width D2 of the first tetraethoxysilane layer 80 is smaller than the channel width D1 of the polysilicon memory channel 30, and the second width D3 of the second tetraethoxysilane layer 90 is smaller than the channel width D1 of the polysilicon memory channel 30. Therein, the first tetraethoxysilane layer 80 and the second tetraethoxysilane layer 90 are deposited through the low-pressure chemical vapor deposition (LPCVD) method. Also, the present invention applies diluted hydrofluoric acid to wet etch the first tetraethoxysilane layer 80 and the second tetraethoxysilane layer 90, whereby the polysilicon memory channel 30 protrudes from the first tetraethoxysilane layer 80 and the second tetraethoxysilane layer 90.

With such configuration, two sides of the polysilicon memory channel 30 protrude out of the first tetraethoxysilane layer 80 and the second tetraethoxysilane layer 90. Because the polysilicon memory channel 30 undergoes different degrees of gate control between its left/right side and its center, the central portion of the polysilicon memory channel 30 will be the most partially depleted portion of the floating body (FB) region. Therefore, in the embodiment, the partially depleted floating body storage region 31 is located in the central region of the polysilicon memory channel 30. Also, the partially depleted floating body storage region 31 effectively stores a large number of holes, so as to enhance the overall memory performance of the present invention (such as achieving a larger memory window, longer memory retention time, etc.).

Referring to FIG. 11 and FIG. 19, in another embodiment, the channel formation step S2 and the second oxide layer formation step S7 are alternately repeated for multiple times, so as to form multiple polysilicon memory channels 30 and second tetraethoxysilane layers 90 disposed in an interleaved arrangement. The iteration of these two steps is ended with the second oxide layer formation step S7, resulting in an arrangement where multiple polysilicon memory channels 30 are interleaved between the first tetraethoxysilane layer 80 and multiple second tetraethoxysilane layers 90. With such configuration, the multiple polysilicon memory channels 30 have multiple partially depleted floating body storage regions 31, enabling the storage of a larger number of holes, thereby further enhancing the overall memory performance of the present invention (such as achieving a larger memory window, longer memory retention time, etc.).

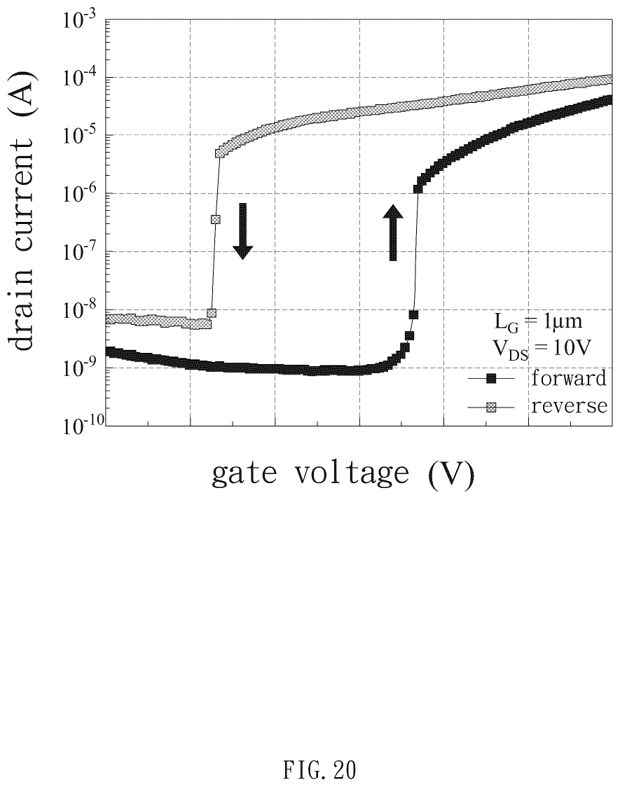

Therefore, referring to FIG. 20, by utilizing the partially depleted floating body storage region 31 within the polysilicon memory channel 30, the present invention is able to store a large number of holes, thereby enhancing the overall performance of the memory, such as achieving a larger memory window (greater than 4V), a longer memory retention time (over 1000 seconds), and a smaller subthreshold swing in the on-state and off-state (less than 60 mV/dec).

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A polysilicon memory structure, comprising:
a silicon base material layer;
a silicon dioxide layer stacked on the silicon base material layer, with a channel setting region disposed on a portion of a surface of the silicon dioxide layer away from the silicon base material layer;
a polysilicon memory channel disposed in the channel setting region and having a partially depleted floating body storage region therein;
a dielectric layer stacked on the silicon dioxide layer and the polysilicon memory channel, and covering a periphery of the polysilicon memory channel; and
a conductive layer stacked on the dielectric layer.

2. The polysilicon memory structure of claim 1, wherein the polysilicon memory channel has a channel width; when the channel width is smaller than a width threshold value, the polysilicon memory structure further comprises a spacer layer disposed on two sides of the polysilicon memory channel.

3. The polysilicon memory structure of claim 2, wherein the spacer layer is disposed at a junction between the polysilicon memory channel and the silicon dioxide layer.

4. The polysilicon memory structure of claim 1, further comprising a silicon nitride layer stacked on one side of the silicon dioxide layer away from the silicon base material layer.

5. The polysilicon memory structure of claim 4, further comprising a first tetraethoxysilane layer and a second tetraethoxysilane layer, the first tetraethoxysilane layer disposed between the silicon nitride layer and the polysilicon memory channel, and the second tetraethoxysilane layer disposed on the polysilicon memory channel.

6. The polysilicon memory structure of claim 5, wherein the first tetraethoxysilane layer has a first width, the second tetraethoxysilane layer has a second width, and the polysilicon memory channel has a channel width; the first width is smaller than the channel width; the second width is smaller than the channel width.

7. The polysilicon memory structure of claim 6, wherein a plurality of the polysilicon memory channels is included, and a plurality of the second tetraethoxysilane layers is included; the polysilicon memory channels and the second tetraethoxysilane layers are disposed in an interleaved arrangement.

8. A manufacturing method of polysilicon memory structure, comprising:
a substrate setting step, providing a substrate having a silicon base material layer and a silicon dioxide layer sequentially stacked from bottom to top;
a channel formation step, depositing an undoped polysilicon layer on the silicon dioxide layer through a chemical vapor deposition method, and performing a partial etching on the undoped polysilicon layer to form a polysilicon memory channel having a partially depleted floating body storage region therein;
a dielectric layer setting step, depositing a dielectric layer on the silicon dioxide layer and the polysilicon memory channel through a chemical vapor deposition method, so that the dielectric layer covers a periphery of the polysilicon memory channel; and
a conductive layer setting step, depositing a conductive layer on the dielectric layer through a chemical vapor deposition method.

9. The manufacturing method of claim 8, wherein before the dielectric layer setting step, a spacer layer setting step is further included; if a channel width of the polysilicon memory channel is smaller than a width threshold value, a spacer layer is deposited on two sides of the polysilicon memory channel through a chemical vapor deposition method.

10. The manufacturing method of claim 9, wherein the spacer layer is disposed at a junction between the polysilicon memory channel and the silicon dioxide layer.

11. The manufacturing method of claim 8, wherein during the substrate setting step, the substrate further comprises a silicon nitride layer, which is stacked on one side of the silicon dioxide layer away from the silicon base material layer.

12. The manufacturing method of claim 11, wherein before the channel formation step, a first oxide layer formation step is further included, wherein a first tetraethoxysilane layer is formed between the silicon nitride layer and the polysilicon memory channel through a chemical vapor deposition method; after the channel formation step, a second oxide layer formation step is further included, wherein a second tetraethoxysilane layer is formed on the polysilicon memory channel through a chemical vapor deposition method.

13. The manufacturing method of claim 12, wherein after the second oxide layer formation step, a raised source/drain formation step is further included, wherein a doped polysilicon layer is deposited on the silicon nitride layer, and the doped polysilicon layer covers the first tetraethoxysilane layer, the polysilicon memory channel, and the second tetraethoxysilane layer; the doped polysilicon layer undergoes a selective etching process to form a raised source in a source region of a transistor and a raised drain in a drain region of the transistor.

14. The manufacturing method of claim 13, wherein after the raised source/drain formation step, an oxide layer etching step is further included, wherein the first tetraethoxysilane layer and the second tetraethoxysilane layer are partially etched, such that the polysilicon memory channel protrudes out of the first tetraethoxysilane layer and the second tetraethoxysilane layer; a first width of the first tetraethoxysilane layer is smaller than a channel width of the polysilicon memory channel, and a second width of the second tetraethoxysilane layer is smaller than the channel width.

15. The manufacturing method of claim 13, wherein the channel formation step and the second oxide layer formation step are alternately repeated for multiple times, so as to form a plurality of the polysilicon memory channels and a plurality of the second tetraethoxysilane layers disposed in an interleaved arrangement.
